(19) United States
(12) Patent Application Publication
(10) Pub. No.: US 2009/0227061 A1
(43) Pub. Date: Sep. 10, 2009

(54) ESTABLISHING A HIGH PHOSPHORUS CONCENTRATION IN SOLAR CELLS

(76) Inventors: Nicholas Bateman, Burlington, MA (US); Atul Gupta, Beverly, MA (US); Christopher Hatem, Salisbury, MA (US); George Papasouliotis, North Andover, MA (US); Helen Maynard, North Reading, MA (US)

Correspondence Address: Nields, Lemack & Frame, LLC, 176 E. MAIN STREET, SUITE 5, WESTBOROUGH, MA, 01581, US

(21) Appl. No.: 12/397,596

(22) Filed: Mar. 4, 2009

Related U.S. Application Data
(60) Provisional application No. 61/033,873, filed on Mar. 5, 2008.
(60) Provisional application No. 61/095,674, filed on Sep. 10, 2008.

(51) Int. Cl. H01L 31/18

(52) U.S. Cl. 438/57

(57) ABSTRACT

Methods of controlling the diffusion of a dopant in a solar cell are disclosed. A second species is used in conjunction with the dopant to modify the diffusion region. For example, phosphorus and boron both diffuse by pairing with interstitial silicon atoms. Thus, by controlling the creation and location of these interstitials, the diffusion rate of the dopant can be controlled. In one embodiment, a heavier element, such as germanium, argon or silicon, is used to create interstitials. Because of the presence of these heavier elements, the dopant diffuses deeper into the substrate. In another embodiment, carbon is implanted. Carbon reduces the number of interstitials, and thus can be used to limit the diffusion of the dopant. In another embodiment, a lighter element, such as helium is used to amorphize the substrate. The crystalline-amorphous interface created limits diffusion of the dopant into the substrate.

This application claims priority of U.S. Provisional Patent Application Ser. No. 61/033,873, filed Mar. 5, 2008, and U.S. Provisional Patent Application Ser. No. 61/095,674, filed Sep. 10, 2008, the disclosures of which are hereby incorporated by reference.

### FIELD

This invention relates to dopant profiles, and, more particularly, to dopant profiles in solar cells.

### BACKGROUND

Ion implantation is a standard technique for introducing conductivity-altering impurities into semiconductor substrates. A desired impurity material is ionized in an ion source, the ions are accelerated to form an ion beam of prescribed energy, and the ion beam is directed at the surface of the substrate. The energetic ions in the beam penetrate into the bulk of the semiconductor material and are embedded into the crystalline lattice of the semiconductor material to form a region of desired conductivity.

Solar cells are typically manufactured using the same processes used for other semiconductor devices, often using silicon as the substrate material. A semiconductor solar cell is a simple device having an in-built electric field that separates the charge carriers generated through the absorption of photons in the semiconductor material. This electric field is typically created through the formation of a p-n junction (diode), which is created by differential doping of the semiconductor material. Doping a part of the semiconductor substrate (e.g. surface region) with impurities of opposite polarity forms a p-n junction that may be used as a photovoltaic device converting light into electricity.

FIG. 1 shows a first embodiment of a solar cell, and is a cross section of a representative substrate 100. Photons 110 enter the solar cell 100 through the top surface 112, as signified by the arrows. These photons pass through an anti-reflective coating 102, designed to maximize the number of photons that penetrate the substrate 100 and minimize those that are reflected away from the substrate.

Internally, the substrate 100 is formed so as to have a p-n junction 120. This junction is shown as being substantially parallel to the top surface 112 of the substrate 100 although there are other implementations where the junction may not be parallel to the surface. The solar cell is fabricated such that the photons enter the substrate through a heavily doped region, also known as the emitter 103. In some embodiments, the emitter 103 may be an n-type doped region, while in other embodiments, the emitter may be a p-type doped region. The photons with sufficient energy (above the bandgap of the semiconductor) are able to promote an electron within the semiconductor material's valence band to the conduction band. Associated with this free electron is a corresponding positively charged hole in the valence band. In order to generate a photocurrent that can drive an external load, these electron hole (e-h) pairs need to be separated. This is done through the built-in electric field at the p-n junction. Thus any e-h pairs that are generated in the depletion region of the p-n junction get separated, as are any other minority carriers that diffuse to the depletion region of the device. Since a majority of the incident photons are absorbed in near surface regions of the device, the minority carriers generated in the emitter need to diffuse across the depth of the emitter to reach the depletion region and get swept across to the other side. Thus to maximize the collection of photo-generated current and minimize the chances of carrier recombination in the emitter, it is preferable to have the emitter region 103 be very shallow.

Some photons pass through the emitter region 103 and enter the base 104. In the scenario where the emitter 103 is an n-type region, the base 104 is a p-type doped region. These photons can then excite electrons within the base 104, which are free to move into the emitter region 103, while the associated holes remain in the base 104. Alternatively, in the case where the emitter 103 is a p-type doped region, the base is an n-type doped region. In this case, these photons can then excite electrons within the base 104, which remain in the base region 104, while the associated holes move into the emitter 103. As a result of the charge separation caused by the presence of this p-n junction, the extra carriers (electrons and holes) generated by the photons can then be used to drive an external load to complete the circuit.

By externally connecting the emitter region 103 to the base 104 through an external load, it is possible to conduct current and therefore provide power. To achieve this, contacts 101, 105, typically metallic, are placed on the outer surface of the emitter region and the base, respectively. Since the base does not receive the photons directly, typically its contact 105 is placed along the entire outer surface. In contrast, the outer surface of the emitter region receives photons and therefore cannot be completely covered with contacts. However, if the electrons have to travel great distances to the contact, the series resistance of the cell increases, which lowers the power output. In an attempt to balance these two considerations (the distance that the free electrons must travel to the contact, and the amount of exposed emitter surface 113) most applications use contacts 101 that are in the form of fingers. FIG. 6 shows a top view of the solar cell of FIG. 1. The contacts are typically formed so as to be relatively thin, while extending the width of the solar cell. In this way, free electrons need not travel great distances, but much of the outer surface of the emitter is exposed to the photons. Typical contact fingers 101 on the front side of the substrate are 0.1 mm with an accuracy of ±0.1 mm. These fingers 101 are typically spaced between 1-5 mm apart from one another. While these dimensions are typical, other dimensions are possible and contemplated herein.

A further enhancement to solar cells is the addition of heavily doped substrate contact regions. FIG. 7 shows a cross section of this enhanced solar cell. The cell is as described above in connection with FIG. 1, but includes heavily doped contact regions 117. These heavily doped contact regions 117 correspond to the areas where the metallic fingers 101 will be affixed to the substrate 100. The introduction of these heavily doped contact regions 117 allows much better contact between the substrate 100 and the metallic fingers 101 and significantly lowers the series resistance of the cell. This pattern of including heavily doped regions on the surface of the substrate is commonly referred to as selective emitter design.

A selective emitter design for a solar cell also has the advantage of higher efficiency cells due to reduced minority carrier losses through recombination due to lower dopant/impurity dose in the exposed regions of the emitter layer. The higher doping under the contact regions provides a field that repels the minority carriers generated in the emitter and pushes them towards the p-n junction.

Solar cells are only one example of a device that uses silicon substrates, but these solar cells are becoming more important globally. Any reduced cost to the manufacturing or production of high-performance solar cells or any efficiency improvement to high-performance solar cells would have a positive impact on the implementation of solar cells worldwide. This will enable the wider availability of this clean energy technology.

Solar cells have previously been manufactured using furnace diffusion for doping and screen printed pastes to form contacts. The paste is printed on the top of an anti-reflective coating. When the paste is fired, it etches through this anti-reflective dielectric coating into the silicon of the solar cell. It will then solidify and provide a contact between metal lines on the surface of the solar cell and the emitter of the solar cell. To work properly, the concentration of the phosphorus at the surface of the solar cell needs to be relatively high. In one example, the phosphorus may need to be approximately 5E20/cm³ for the solar cell to operate properly. This high phosphorus concentration at the surface of the emitter may entail some compromises in solar cell design. A lighter doping may be preferable for charge generation between the contacts or in the area of the solar cell exposed to light. A deeper dopant distribution beneath the contacts may be preferable to have a lower resistance between the contacts and the remainder of the emitter. Both these desired configurations are limited by the high surface concentration of phosphorus used to enable good contacts and proper operation of the solar cell. Accordingly, there is a need in the art for improved dopant profiles in solar cells and, more particularly, methods to make a dopant profile in a solar cell that has a large surface concentration of phosphorus.

### SUMMARY

The problems of the prior art are overcome by the methods disclosed herein which limit the diffusion of a dopant in a substrate. A second species is used in conjunction with the dopant to modify the diffusion region. For example, phosphorus and boron both diffuse by pairing with interstitial silicon atoms. Thus, by controlling the creation and location of these interstitials, the diffusion rate of the dopant can be controlled. In one embodiment, a heavier element, such as germanium, argon or silicon, is used to create interstitials. A dopant is also introduced, and because of the presence of these heavier elements, diffuses deeper into the substrate. In another embodiment, carbon is implanted. Carbon can be used to limit the diffusion of the dopant. In another embodiment, a lighter element, such as helium is used to amorphize the substrate. The crystalline-amorphous interface created cannot be penetrated by the dopant, thereby limiting its diffusion into the substrate.

### BRIEF DESCRIPTION OF THE DRAWINGS

For a better understanding of the present disclosure, reference is made to the accompanying drawings, which are incorporated herein by reference and in which:

FIG. 1 is an embodiment of an exemplary solar cell;

FIG. 2 is a process flow for manufacturing a solar cell;

FIGS. 3A-3C are embodiments of a process flow for manufacturing a solar cell;

FIGS. 4A-4B are embodiments of a process flow for manufacturing a solar cell;

FIGS. 5A-5B compare dopant concentration versus depth for various species and implant energies;

FIG. 6 shows a top view of the solar cell of FIG. 1;

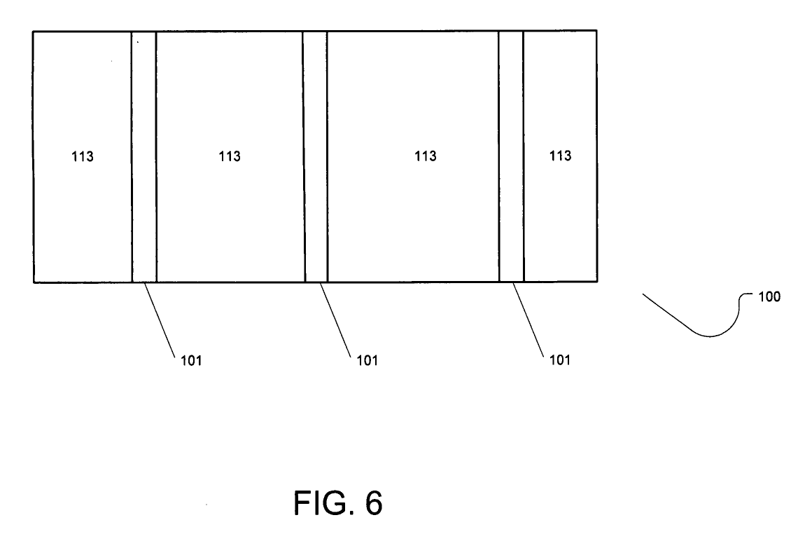

FIG. 7 shows a cross section of a solar cell using selective emitter design; and

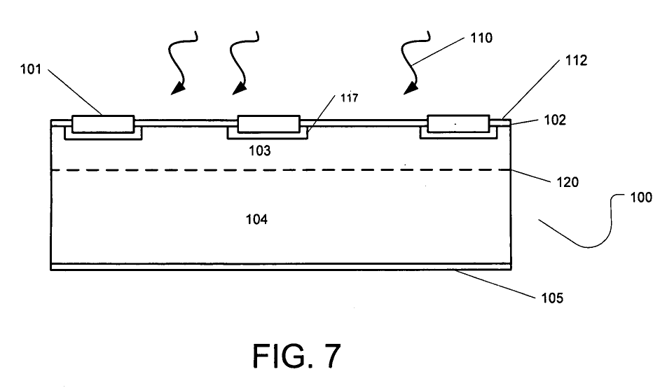

FIG. 8 shows a cross section of an interdigitated back contact (IBC) solar cell.

### DETAILED DESCRIPTION

The embodiments of the process described herein may be performed by, for example, a beam-line ion implanter or a plasma doping ion implanter. Such a plasma doping ion implanter may use RF or other plasma generation sources. Other plasma processing equipment or equipment that generates ions also may be used. Thermal or furnace diffusion, pastes on the surface of the solar cell substrate that are heated, epitaxial growth, or laser doping also may be used to perform certain embodiments of the process described herein. Furthermore, while a silicon solar cell is specifically disclosed, other solar cell substrate materials also may benefit from embodiments of the process described herein. While phosphorus is specifically disclosed, other dopants also may be used in the embodiments of the process described herein.

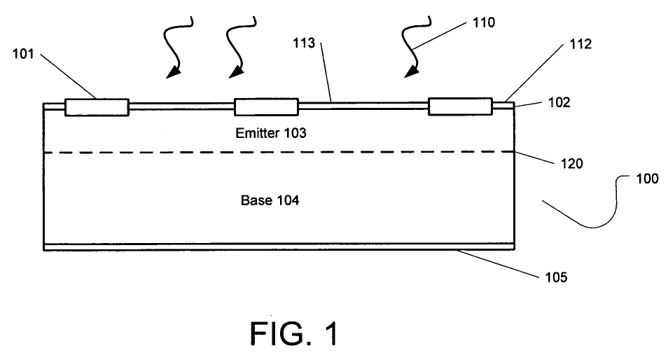

As described above, FIG. 1 is an embodiment of an exemplary solar cell. Other embodiments or designs are possible and the embodiments of the process described herein are not solely limited to the solar cell 100 illustrated in FIG. 1. Solar cell 100 includes contacts 101 and backside contact 105. Underneath the dielectric 102 is the emitter 103 and base 104 that make up the p-n junction in the solar cell 100. The emitter 103 and base 104 may be either p-type or n-type depending on the solar cell 100 design. In some instances, this dielectric 102 may be a dielectric passivation layer or an antireflective coating.

The required high surface concentration of phosphorus may limit the design of the solar cell. If the solar cell does not have patterned doping (i.e., doping of a particular pattern in the solar cell), then the carrier generation and charge collection between the contacts would benefit from a lower phosphorus doping level. However, it is difficult to lower the level of phosphorus without lowering the surface concentration of phosphorus or making the junction shallower. Lowering the surface concentration affects performance of the solar cell and making the junction shallower may cause the contacts to short through the junction. If the solar cell has patterned doping, the high phosphorus surface concentration makes it difficult to minimize the sheet resistance under the contacts. For carriers to be transported efficiently to the contacts, low resistivity under the contacts may be required. A deep dopant profile may best provide this low resistivity and also may provide lateral electric fields in the bulk silicon that may assist carriers to drift toward the junctions. However, it may be difficult to have both a deep dopant profile and the high surface concentration of a dopant needed for screen printed contacts.

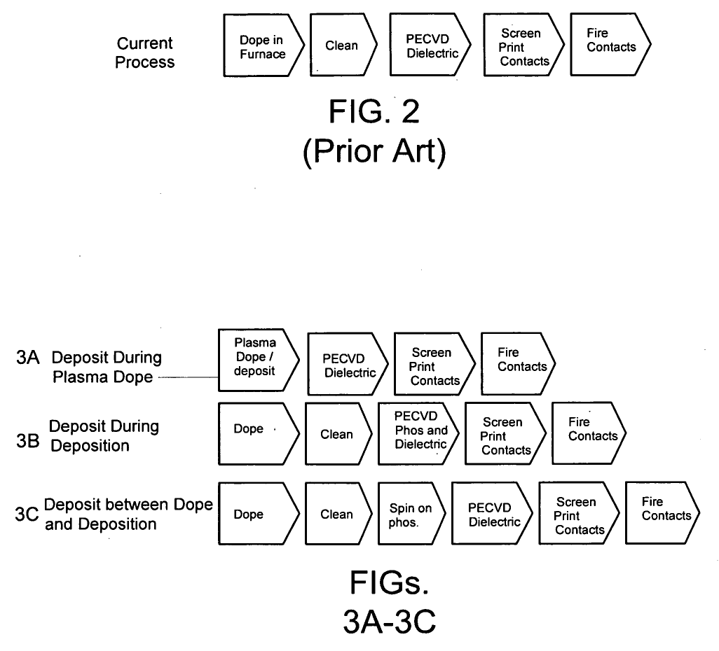

FIG. 2 is a process flow for manufacturing a solar cell. The standard manufacturing process includes doping the solar cell in a furnace. This is typically done using a gaseous or solid source in the furnace. The solar cell is then cleaned to remove any phosphorus-silicate glass on the surface of the solar cell that is left after the doping step. The cleaning may be a wet step in one embodiment. The dielectric is then added. Plasma-enhanced chemical vapor deposition (PECVD) or sputtering may be used to deposit silicon nitride on the surface of the cell. In another embodiment, silicon oxide is used as a dielectric. These dielectrics serve as antireflective coatings. Then the screen printed paste is disposed on the solar cell in the pattern of the contacts. The contacts are then fired in a furnace. During this firing, the glass frit in the paste chemically etches the dielectric and melts some of the silicon underneath the dielectric. When the melt solidifies, a contact is made between the silicon and the metal on the other side of the dielectric.

The paste composition in the standard manufacturing process is chosen to ensure that it reliably etches through the dielectric, that it does not melt so much silicon as to short out the p-n junction, and that a minimal resistance is found in the point contacts between the silicon and the metal. To generate contacts with low resistance during firing, a high surface concentration of phosphorus is required near the silicon-dielectric interface. The phosphorus at the interface may be interstitial in the silicon crystal lattice in one embodiment.

There are several different embodiments that may be used to maintain a high surface concentration of phosphorus to enable good contacting with fired screen printed contacts. For example, phosphorus may be deposited during doping, between doping and dielectric deposition, or at the beginning of the dielectric deposition. Phosphorus may be added through ion implantation after doping either into or through the dielectric layer. In one instance, diffusion of the phosphorus may be limited during doping or annealing by introducing an additional species into the silicon lattice.

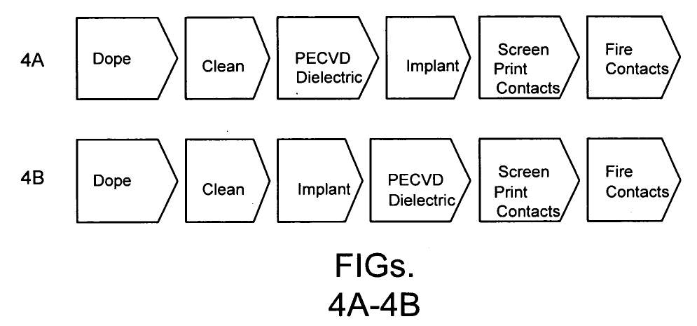

FIGS. 3A-3C are embodiments of a process flow for manufacturing a solar cell, in which additional phosphorus is deposited on the substrate. In the embodiments of the processes described herein, doping may be accomplished in a furnace, through ion implantation, or by using another process. As illustrated in FIG. 3A, phosphorus may be deposited during doping using, for example, a plasma doping ion implanter. If the plasma voltage is cycled, it is possible to implant phosphorus into the substrate when the substrate is biased relative to the plasma and to deposit phosphorus onto the surface of the substrate when it is at the same potential as the plasma. Both the voltage applied to the solar cell and the gas mixture composition may be graded during the doping process. For example, when the voltage difference between the substrate and the plasma is significant, the phosphorus ions from the plasma will be accelerated toward the substrate, and implanted within the substrate. When this voltage difference is small or zero, the phosphorus ions will accelerate much more slowly toward the substrate, thereby leaving a layer of phosphorus ions on the top surface. Additionally, the composition of the gas used to create the plasma can be modified, so as to increase or decrease the concentration of phosphorus ions as required. Thus, the phosphorus dopant profile in the solar cell may be controlled by the voltage applied to the solar cell and the composition of the gas mixture. In one embodiment, a gas containing phosphorus is injected into a plasma chamber. The substrate is then subjected to two voltages; one to implant phosphorus into the substrate; and a second to implant phosphorus onto the surface of the substrate. The amount of time that the substrate is subjected to a particular voltage will determine the concentration of phosphorus deposited. For example, in one embodiment, the first voltage may be about 10 k volts and be applied for less than a minute, while the second voltage is less than 2 k volts.

In the embodiment of FIG. 3B, phosphorus is deposited during a chemical vapor composition (CVD) or PECVD at the same time the dielectric is deposited. Common dielectrics are typically silicon-based compounds, such as silicon oxide or silicon nitride. Thus, the concentration of the phosphorus can be graded by changing the relative gas flow of silane (or another silicon-containing gas used to deposit the dielectric) and phosphine (or another phosphorus-containing gas used to deposit the phosphorus). The phosphorus concentration may be graded to keep most phosphorus next to the silicon-dielectric interface. In one embodiment, the phosphorus concentration is graded by having a relatively large flow of a phosphorus-bearing gas at the start of the deposition. As the deposition proceeds, the flow of the phosphorus-containing gas is reduced, thus reducing the relative amount of phosphorus in the deposited dielectric.

In the embodiment of FIG. 3C, phosphorus may be deposited in a separate process step, such as in a spin coating process. Spin coating involves the deposition of a material onto a substrate, preferably the center thereof. The substrate is then spun, such as about 500 rpm, so as to spread the material across the surface of the substrate. The substrate is then spun at a higher speed, such as between 2000 and 4000 rpm to create a thin, uniform-thickness coating on the substrate. In some embodiments, the phosphorus may be deposited using, for example, phosphorus-rich nanoparticles.

In another embodiment, the phosphorus can be sprayed onto the surface of the substrate, such as via an atomizing nozzle.

In another embodiment, a thin layer of phosphorus may be deposited in a PECVD tool immediately before dielectric deposition. Typically, chemical vapor depositions take place over extended periods of time, with relatively stable operating parameters. However, in some embodiments, the phosphorus may be introduced in a “flash” deposition, wherein the phosphorus gas is introduced only for a brief time period, such as less than 30 seconds, thereby limiting the exposure of the substrate to the phosphorus and minimizing into diffusion.

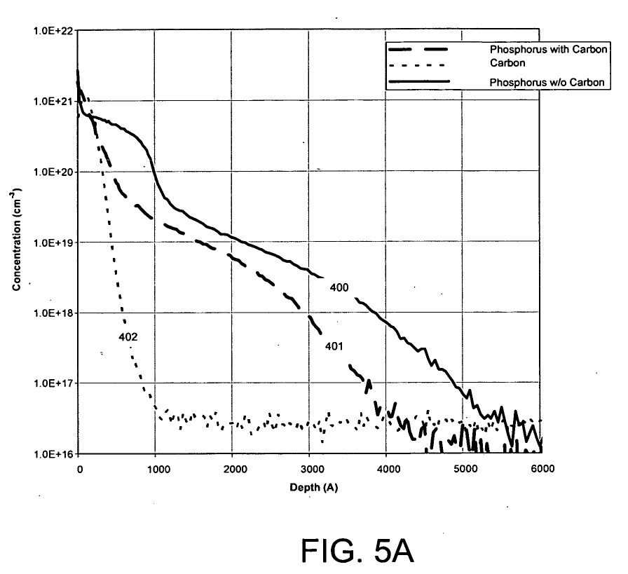

FIGS. 4A-4B are embodiments of a process flow for manufacturing a solar cell, in which additional phosphorus is implanted into or through the dielectric coating. To ensure that good contacts are made with fired screen printed pastes, phosphorus ions can be introduced into the silicon or dielectric using ion implantation before the formation of the dielectric (as shown in FIG. 4B) or after the formation of the dielectric and before the screen printing of the paste (as shown in FIG. 4A). This step will introduce interstitial phosphorus into the silicon-dielectric interface. This may relax the requirement of phosphorus introduced during the doping step in order to optimize the doping process step. Introducing the phosphorus may be configured so that the dopant profile is stopped in the dielectric. If phosphorus is implanted into the underlying silicon, the implanted phosphorus should either be shallow enough that the firing of the contacts through the dielectric will melt all the silicon affected by the implant or the implant should amorphize the silicon so that the firing will selectively melt the amorphized silicon.

If the implanted ions pass through the dielectric and are implanted into the substrate, these ions leave damage in the substrate. The process flow allows only a short thermal step that may not anneal that damage. If the thermal step is inadequate to anneal the damage, then the paste may be precisely aligned with the implanted ions so that all of the unannealed silicon in the substrate will be consumed when the paste fires through the dielectric. Alternately, if the silicon under the dielectric is amorphized, the amorphized material will preferentially melt when the paste fires through the dielectric. In this case, the alignment may not be as critical since the damaged material will be incorporated into the contact with the paste.

In the embodiment of FIG. 4A, phosphorus is implanted at least partly after dielectric deposition using PECVD or CVD. This implantation may be through the dielectric and into the silicon. In one embodiment, this implantation is performed without the use of a pattern (i.e. a “blanket” implant). In one instance, the phosphorus is implanted into the dielectric. The implant energy of the phosphorus may be limited to ensure that the implanted beam cannot reach the substrate. In this instance, the process step also may introduce hydrogen into the dielectric for passivation. In another instance, the phosphorus is implanted through the dielectric and into the silicon. In an alternative embodiment, the phosphorus can be performed using a pattern that matches the contact pattern (possibly using a “patterned” implant). In one instance, the phosphorus is implanted into the dielectric using a pattern. The pattern may be, for example, a hard mask, a shadow mask or a stencil mask. In another instance, the phosphorus is implanted through the dielectric and into the substrate.

In the embodiment of FIG. 4B, phosphorus is implanted in a pattern that matches the contact pattern after the doping step and at least partly before deposition of the dielectric. This may use a mask in one instance.

The previous embodiments illustrate methods of introducing additional dopants and modifying the dopant profile through deposition or implantation of phosphorus. In another embodiment, diffusion of dopants may be modified by introducing a second species into the silicon lattice either before or after introducing the dopant. If the second species competes with the dopant for diffusion and diffuses more slowly than the dopant, the resulting dopant profile may be shallower due to the presence of the second species. If the second species does not compete with the dopant for diffusion and instead enhances diffusion by, for example, increasing the vacancies in the crystal lattice, then the resulting dopant profile will be made deeper.

As described above, screen fired contacts require high dopant concentrations at the surface of the semiconductor. In one particular embodiment, a higher dopant concentration may be desired immediately beneath the surface of the solar cell to repel minority carriers from the surface and to limit surface recombination. Such concentrations at this depth are difficult to maintain during the thermal processing performed on crystalline silicon solar cells. Dopants placed in the silicon will diffuse and, therefore, the dopant distribution within the solar cell will change. This diffusion can limit thermal processing options or dopant profiles that can be achieved.

In this embodiment, diffusion of dopant atoms is modified by introducing a second species into the silicon matrix. The second species may compete with the diffusion of the dopant or inhibit diffusion of the dopant in some other way. Alternatively, the second species may increase diffusion of the dopant by increasing vacancies or interstitials in the crystal lattice. The qualities or characteristics of the second species will change the effect of thermal processing on the dopant distribution. Changes in the silicon lattice caused by the implantation of the second species also may affect the diffusion of the dopant.

The dopant atoms may be introduced into the silicon matrix of the solar cell using, for example, ion implantation or furnace diffusion. The second species distribution in the silicon may restrict the diffusion of the dopant in the silicon matrix. In the case of furnace diffusion, a gas containing both the dopant and the second species can be used, or alternatively, two gases can be used, where one contains the dopant and the other contains the second species. If two gases are used, these gases can be introduced simultaneously, or one may be introduced prior to the second. In the case of ion implantation, the dopant and second species may be introduced simultaneously through acceleration and implantation of a molecule containing both atoms or through acceleration and implantation of an ion beam that contains both atoms and that has not been mass analyzed. In another particular embodiment, the second species may be the same type of dopant (i.e., acceptor or donor).

In one embodiment, a second species such as, for example, a heavier element, such as but not limited to silicon, germanium, or argon, is implanted into the silicon. The implantation of these atoms increases the number of interstitial silicon atoms and the number of vacancies in the lattice of the solar cell. The level of lattice damage (i.e. slight damage, heavy damage, fully amorphized) is a function of the atomic mass of the ion, the energy of the implant and the total dose. For example, a heavy ion, such as arsenic, would require lower energy and lower dose, as compared to a phosphorus or carbon implant, to create a specific level of lattice damage. Those of ordinary skill in the art can determine the appropriate operating parameters to achieve the required level of lattice damage. Phosphorus diffuses by pairing with interstitial silicon. The lattice damage caused by this implantation causes a large number of interstitial silicon atoms, thereby increasing the diffusion of phosphorus deeper into the substrate. This may allow a deeper dopant profile to lower sheet resistance beneath the contact, such as for boron doping beneath a contact in a PERL (passivated emitter, rear locally diffused) solar cell.

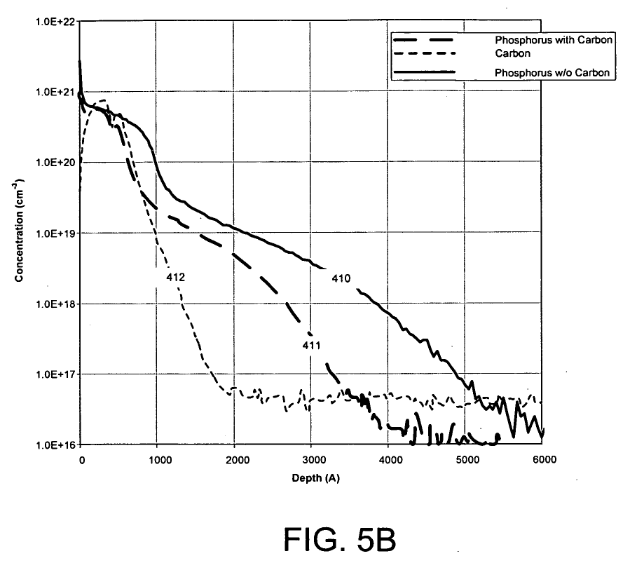

In another embodiment, the dopant is phosphorus and the second species is carbon. The presence of carbon suppresses phosphorus diffusion, as shown in FIGS. 5A-B. FIG. 5A compares dopant concentration versus depth for phosphorus and carbon. Profile 400 is the result of a phosphorus implant without a second species after a 30 minute anneal. Note that the dopant concentration has a nearly linear with depth. Profile 402 is a carbon implant after a 30 minute anneal. Profile 401 is the result of a phosphorus implant with carbon after a 30 minute anneal. The profiles shown in FIG. 5A were created using a carbon implant of 4.5 keV Carbon 3e15/cm² dose, and a phosphorus implant of 10 keV Phos 3.7e15/cm² dose. These energies correspond to a 14.5 keV PC molecule. The carbon and the phosphorus in profile 401 were implanted prior to the anneal. FIG. 5B shows a second graph comparing dopant concentration versus depth for phosphorus and carbon. In this example, the phosphorus implant 410 is identical to that of FIG. 5A, however, the carbon implant 412 is performed at 12 keV. Note that the carbon diffuses deeper in this instance. Either the dopant or the carbon can be introduced first, or the carbon and dopant may be introduced simultaneously. In one particular embodiment, a molecule containing both carbon and a dopant is ionized and implanted. Both species may be introduced prior to the thermal cycle. As described above, ion implantation, furnace diffusion, or other methods may be used to introduce the species. Both species need not be introduced using the same mechanism. For example, in one particular embodiment, the carbon is implanted in the substrate, while furnace diffusion is used to introduce phosphorus to the substrate.

By introducing carbon, the phosphorus surface concentration is increased and junction depth is decreased after the anneal in profile 401 compared to profile 400. The amount of phosphorus that remains at the surface (depth closer to 0 Angstroms) is higher in profile 401 than profile 400. Furthermore, the depth that the phosphorus diffuses to is shallower in profile 401 than profile 400. This is at least partly due to the presence of carbon in the silicon matrix of the solar cell. Similarly, the depth that the phosphorus diffuses to is shallower in profile 411 than profile 410. The higher surface concentration of phosphorus may be advantageous for passivation of the surface of the solar cell and to make contacts with the screen printed pastes. Carbon implant energy may be between 1 keV and 60 keV.

In yet another embodiment, a species such as helium is implanted into the silicon of the solar cell at a dose high enough to amorphize the silicon. This destroys the long-range crystal lattice structure of the silicon. At the end-of-range of this implant, there will be an interface between the amorphized silicon and the underlying crystalline silicon. The diffusion of dopant atoms across this interface will be at least partly inhibited. As the crystalline silicon regrows during the anneal process, this amorphous-crystalline interface will move closer to the surface of the silicon. Other lighter species, such as hydrogen, also may be used to amorphize the silicon.

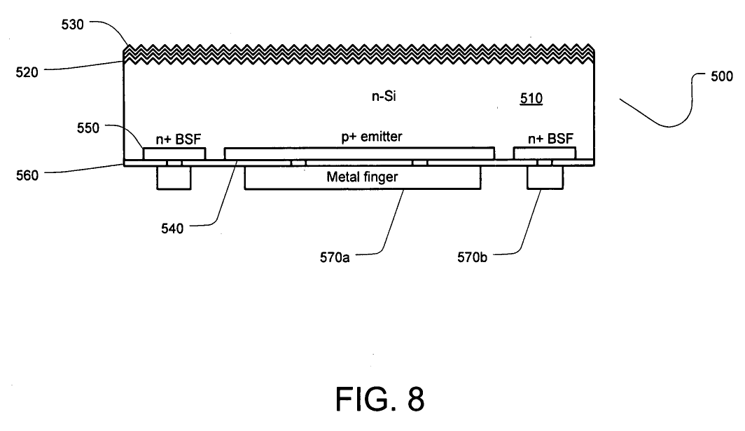

The above techniques disclosed methods of modifying dopant concentrations for an emitter of a solar cell by the introduction of phosphorus. However, alternative types of solar cells, such as interdigitated back contact (IBC) solar cells) can benefit from the techniques described herein. For example, FIG. 8 shows a cross section of an IBC solar cell. Fundamentally, the physics of this solar cell are similar to those of the solar cell of FIG. 1, in which a p-n junction is used to create an electric field which separates the generated electron hole pairs. However, rather than create the p-n junction across the entire substrate, as done in the previous embodiment, the junctions are only created in portions of the substrate 500. In this embodiment, a negatively doped silicon substrate 510 is used. In certain embodiments, a more negatively biased front surface field (FSF) 520 is created by implanting addition n-type dopants in the front surface. This FSF can be created using the techniques described above. This front surface is then coated with an anti-reflective material 530. This front surface is often etched to create a sawtooth or other non-planar surface, so as to increase surface area. The metallic contacts or fingers 570 are all located on the bottom surface of the substrate. Certain portions of the bottom surface are implanted with p-type dopants to create emitters 540. Other portions are implanted with n-type dopants to create more negatively biased back surface field 550. A layer of reflective coating 560 is then used to coat the back surface. Metal fingers 570a are attached to the emitter 540 and fingers 570b attaches to the BSF 550.

The p+ emitter regions can be fabricated using the techniques described above. In this embodiment, rather than using phosphorus, a p-type dopant, such as boron is used. For example, a pattern is used to define the area which will form the p+ emitter. Boron is then diffused into the substrate, using any of the techniques taught above.

The terms and expressions which have been employed herein are used as terms of description and not of limitation, and there is no intention in the use of such terms and expressions of excluding any equivalents of the features shown and described (or portions thereof). It is also recognized that various modifications are possible within the scope of the claims. Other modifications, variations, and alternatives are also possible. Accordingly, the foregoing description is by way of example only and is not intended as limiting.

What is claimed is:

1. A method of creating a high dopant concentration near the surface of a solar cell, comprising;
utilizing a silicon substrate;
introducing a dopant into said substrate; and
introducing carbon into said substrate, wherein said carbon limits the diffusion of said dopant.

2. The method of claim 1, wherein said dopant and said carbon are introduced simultaneously.

3. The method of claim 3, wherein said dopant and said carbon are introduced via ion implantation, wherein a molecule comprising said dopant and said carbon is ionized.

4. The method of claim 3, wherein said dopant and said carbon are introduced via ion implantation, wherein said ion implantation is performed without a mass analyzer.

5. The method of claim 3, wherein said dopant and said carbon are introduced via furnace diffusion, wherein a gas comprising both said dopant and said carbon is heated.

6. The method of claim 1, wherein said dopant and said carbon are introduced sequentially.

7. The method of claim 6, wherein said dopant and said carbon are introduced via ion implantation.

8. The method of claim 1, further comprising determining an energy level for said carbon implant, so as to achieve said high dopant concentration near the surface.

9. The method of claim 8, wherein said energy level is between 1 keV and 60 keV.

10. The method of claim 1, wherein said carbon is introduced via ion implantation, and said dopant is introduced via furnace diffusion.

11. The method of claim 1, wherein said dopant is selected from the group consisting of phosphorus and boron.

12. The method of claim 1, further comprising performing a thermal anneal subsequent to said introduction of said dopant and said carbon.

13. A method of modifying a dopant concentration of a solar cell, comprising;
utilizing a silicon substrate;
introducing a dopant into said substrate; and
introducing a second species into said substrate, wherein said second species increases the number of silicon interstitials within said solar cell.

14. The method of claim 13, wherein said dopant is selected from the group consisting of phosphorus and boron.

15. The method of claim 13, further comprising performing a thermal anneal subsequent to said introduction of said dopant and said second species.

16. The method of claim 13, wherein said second species is selected from the group consisting of argon, germanium and silicon.

17. A method of creating a high dopant concentration near the surface of a solar cell, comprising;
utilizing a silicon substrate;
introducing a dopant into said substrate; and
introducing helium into said substrate, wherein said helium limits the diffusion of said dopant.

18. The method of claim 17, wherein said helium is implanted with sufficient dose such that at least a portion of said substrate is amorphized.

19. The method of claim 17, further comprises performing an anneal subsequent to said two introducing steps.

20. The method of claim 17, where said dopant is selected from the group consisting of phosphorus or boron.
